(19) United States
(12) Patent Application Publication
(10) Pub. No.: US 2014/0312488 A1
(43) Pub. Date: Oct. 23, 2014

(54) METHOD OF MANUFACTURING WIRING BOARD UNIT, METHOD OF MANUFACTURING INSERTION BASE, WIRING BOARD UNIT, AND INSERTION BASE

(71) Applicant: FUJITSU LIMITED, Kawasaki-shi (JP)

(72) Inventor: Takashi FUKUDA, Machida (JP)

(73) Assignee: FUJITSU LIMITED, Kawasaki-shi (JP)

(21) Appl. No.: 14/230,188

(22) Filed: Mar. 31, 2014

(30) Foreign Application Priority Data
Apr. 18, 2013 (JP) 2013-087757

(51) Int. Cl. H01L 23/00

(52) U.S. Cl. CPC H01L 24/83; H01L 24/26
USPC 257/734; 438/106

(57) ABSTRACT

A method of manufacturing a wiring board unit, the wiring board unit including a semiconductor package that includes a memory chip, a wiring board on which the semiconductor package is mounted, and an insertion base inserted between the wiring board and the semiconductor package, the method includes: forming a plurality of connection portion groups in a base material, the connection portion groups each including a plurality of connection portions that each electrically connect a board-side pad of the wiring board and an external terminal of the semiconductor package to each other; forming the insertion base such that resistances of the connection portions included in the connection portion groups are adjusted in accordance with types of target memory chips; and connecting the external terminals and the board-side pads to one another by using the connection portion group selected in accordance with the type of the memory chip.

### CROSS-REFERENCE TO RELATED APPLICATION

This application is based upon and claims the benefit of priority from the prior Japanese Patent Application No. 2013-087757 filed on Apr. 18, 2013, the entire contents of which are incorporated herein by reference.

### FIELD

The embodiment herein is related to a method of manufacturing a wiring board unit, a method of manufacturing an insertion base, the wiring board unit, and the insertion base.

### BACKGROUND

Nowadays, further increasing of the speed at which signals are transmitted between large scale integrations (LSIs) is desired. Examples of such transmission include signal transmission between a logic chip (memory controller) such as an application specific integrated circuit (ASIC) and a memory chip such as a dynamic random access memory (DRAM). In some systems that transmit signals between LSIs, a logic chip is connected to a plurality of memory chips in a daisy chain configuration. The daisy chain configuration may also be referred to as a fly-by configuration or a T-branch configuration, or sometimes compared to a potato vine.

FIG. 1 is a block diagram generally illustrating an example of a related-art signal transmission system (bus system). Referring to FIG. 1, reference numeral 101 denotes a logic chip, reference numeral 102 denotes a signal transmission path (bus), reference numeral 103 denotes memory chips, and reference numeral 104 denotes stub resistors. A plurality of the memory chips 103 are connected to the logic chip 101 through the bus 102 in a daisy chain configuration. Here, the bus 102 includes a main line 102A and branch lines 102B that branch off from the main line 102A.

In the bus system utilizing the daisy chain configuration illustrated in FIG. 1, multipath reflection, in which signals from the logic chip 101 are reflected in multiple paths in each memory chip 103, may occur. The reflected waves are superposed with one another, thereby the signal waveform is broken. In order to address this, a related-art technology is known in which the stub resistors 104 are inserted in the branch lines 102B. By inserting the stub resistor 104 in each of the branch lines 102B, multipath reflection of the signals may be suppressed, and accordingly, breaking of the signal waveform may be suppressed.

A technology to address noise in memory chips has been proposed. This technology addresses the noise by, for example, connecting resistors in series to pads for a chip formed in memory chips on a board to which a plurality of memory chips are mounted. Other methods of improving the quality of the waveform of the signals transmitted through a bus include a method in which the lengths of branch lines are adjusted so that reflected waves of the branch lines are not superposed with one another, a method in which impedances at branching portions are adjusted, and so forth.

However, in any of the related-art methods, an additional mounting region is usually provided in a wiring board so as to improve the quality of the waveform of signals being transmitted. For example, in order to provide stub resistors in branch lines connected to memory chips mounted on a wiring board, mounting regions for the stub resistors are provided. Thus, in some cases, wiring regions for the branch lines are unavoidably enlarged.

When the stub resistors are inserted in the branch lines connected to the memory chips, the signal waveform becomes gentle as illustrated in, for example, FIG. 2, and accordingly, the quality of the waveform is improved. However, there may be a case where signal delays are not suppressed or the signal delays become worse due to insertion of the stub resistors. Here, various types of signals such as address signals, clock signals, command signals, data signals, and the like are transmitted to the memory chips. FIG. 3 illustrates an example of the relationships between the types of the signals input to the memory chips and propagation delay time. In the example illustrated in FIG. 2, the relationships between the types of the input signals and the propagation delay time are represented for each of the memory chips supplied by a plurality of vendors (manufacturers). As illustrated in FIG. 3, when there is a difference in the types (characteristics) of the memory chips such as a difference in the vendors (manufacturers) of the memory chips, the propagation delay time significantly varies even for the same type of the signal.

When, as is the case with the related-art, the stub resistors are directly disposed on the wiring board, the resistance of each of the stub resistors is a unique value. Thus, when memory chips of different types supplied from a plurality of vendors are selected and mounted, or when memory chips of different types are combined and mounted on a board, the stub resistors are not adjusted in accordance with characteristics of each of the memory chips. This may lead to a signal delay. Likewise, even in the case where, for example, the memory chips are supplied from a single vendor, when an existing memory chip is replaced with a memory chip of a different model number in rework, it may be difficult to ensure the quality of the signal waveform and suppress signal delays. When memory chips of different types are mounted on a wiring board, the routing topology itself of the wiring board is unavoidably changed in the related-art in order to ensure the quality of the signal waveform and suppress signal delays.

The following is reference documents:
[Document 1] Japanese Laid-open Patent Publication No. 11-74449, and
[Document 2] Japanese Laid-open Patent Publication No. 2008-103495.

### SUMMARY

According to an aspect of the invention, a method of manufacturing a wiring board unit, the wiring board unit including a semiconductor package that includes a memory chip, a wiring board on which the semiconductor package is mounted, and an insertion base inserted between the wiring board and the semiconductor package, the method includes: forming a plurality of connection portion groups in a base material, the connection portion groups each including a plurality of connection portions that each electrically connect a board-side pad of the wiring board and an external terminal of the semiconductor package to each other, the connection portion groups being selectively used in accordance with a type of the memory chip; forming the insertion base such that resistances of the connection portions included in the connection portion groups are adjusted in accordance with types of target memory chips; and connecting the external terminals and the board-side pads to one another by using the connection portion group selected in accordance with the type of the memory chip from the plurality of connection portion groups of the insertion base having been formed.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram generally illustrating an example of a related-art signal transmission system;

FIG. 2 illustrates the difference in a signal waveform observed when a stub resistor is used and not used;

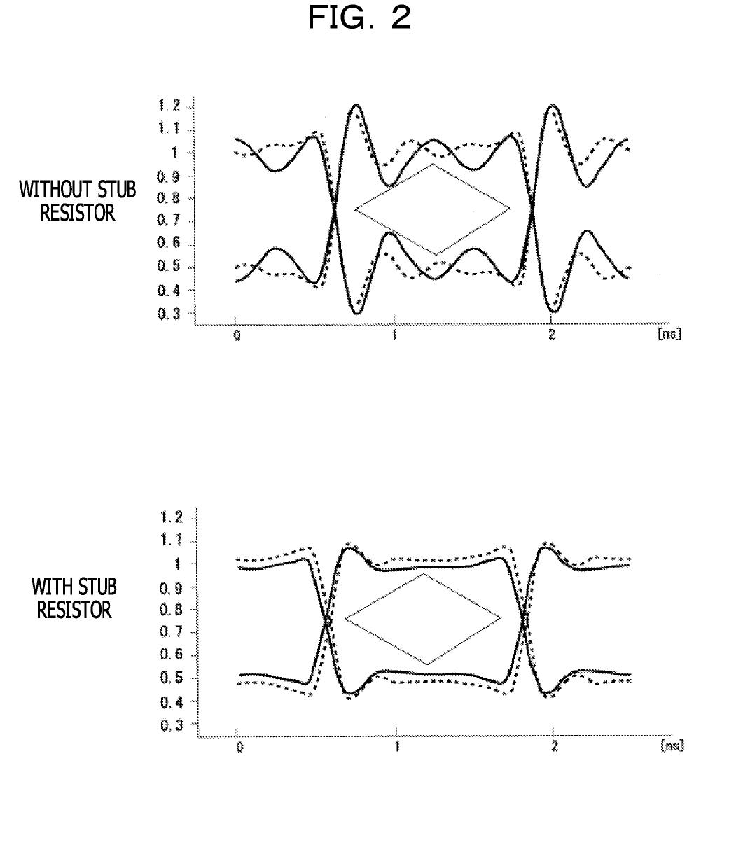

FIG. 3 illustrates an example of the relationships between the types of signals input to memory chips and propagation delay time;

FIG. 4 generally illustrates a wiring board unit according to an embodiment;

FIG. 5 illustrates a detailed structure of a memory controller according to the embodiment;

FIG. 6 illustrates a detailed structure of a memory package and an insertion base according to the embodiment;

FIGS. 7A and 7B illustrate arrangement patterns of solder balls in memory packages according to the embodiment;

FIG. 8 illustrates arrangement patterns of connection portions of the insertion base according to the embodiment;

FIG. 9 is a first diagram illustrating a manufacturing process of the insertion base according to the embodiment;

FIG. 10 is a second diagram illustrating the manufacturing process of the insertion base according to the embodiment;

FIG. 11 is an enlarged view schematically illustrating part of an upper surface of a base material according to the embodiment;

FIG. 12 is a third diagram illustrating the manufacturing process of the insertion base according to the embodiment;

FIG. 13 is a fourth diagram illustrating the manufacturing process of the insertion base according to the embodiment;

FIG. 14 is a fifth diagram illustrating the manufacturing process of the insertion base according to the embodiment;

FIG. 15 is a sixth diagram illustrating the manufacturing process of the insertion base according to the embodiment;

FIG. 16 is a seventh diagram illustrating the manufacturing process of the insertion base according to the embodiment;

FIG. 17 is an eighth diagram illustrating the manufacturing process of the insertion base according to the embodiment;

FIG. 18 is a ninth diagram illustrating the manufacturing process of the insertion base according to the embodiment;

FIG. 19 is a tenth diagram illustrating the manufacturing process of the insertion base according to the embodiment;

FIG. 20 is an eleventh diagram illustrating the manufacturing process of the insertion base according to the embodiment;

FIG. 21 is a first diagram illustrating a manufacturing process of the wiring board unit according to the embodiment;

FIG. 22 is a second diagram illustrating the manufacturing process of the wiring board unit according to the embodiment;

FIGS. 23A to 23C illustrate modified examples of the shapes of pads formed on the insertion base according to the embodiment;

FIG. 24 is a first diagram illustrating identification markers of the insertion base according to the embodiment;

FIG. 25 is a second diagram illustrating the identification markers of the insertion base according to the embodiment;

FIG. 26 illustrates a memory package for 16-bit according to the embodiment;

FIG. 27 illustrates a memory package for 8-bit according to the embodiment;

FIGS. 28A and 28B illustrate the insertion base common to the memory package for 16-bit and the memory package for 8-bit according to the embodiment;

FIG. 29 generally illustrates a wiring board unit according to a variant; and

FIG. 30 illustrates a manufacturing process of a wiring board unit according to the variant.

### DESCRIPTION OF EMBODIMENT

An embodiment of a wiring board unit and a method of manufacturing the wiring board unit will be described in detail below with reference to the drawings.

Wiring Board Unit

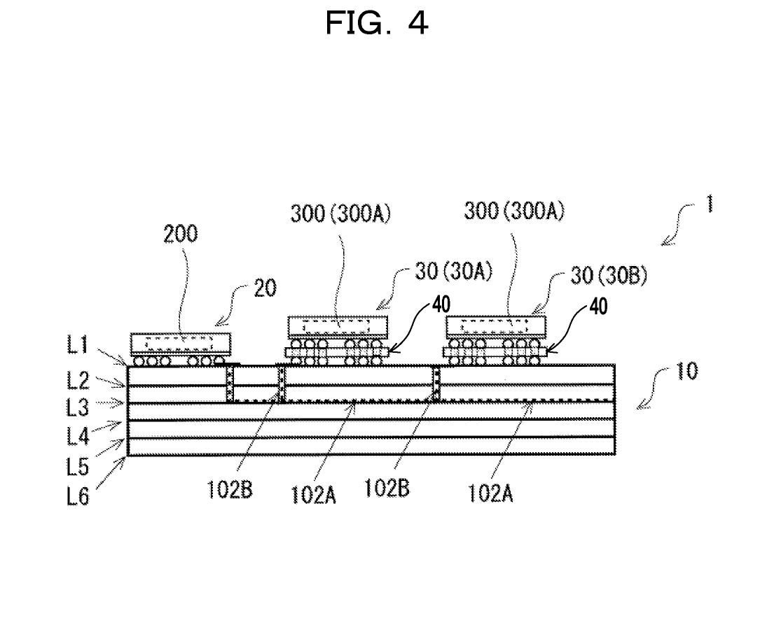

FIG. 4 generally illustrates a wiring board unit 1 according to an embodiment generally illustrating a sectional structure of the wiring board unit 1. The wiring board unit 1 includes components such as a printed wiring board 10, a memory controller (processor) 20, a plurality of memory packages 30 (two memory packages 30A and 30B in an example illustrated in FIG. 4), and insertion bases 40.

The wiring board unit 1 is housed in a housing of an electronic device such as, for example, a computer machine. The printed wiring board 10 is a mother board (system board) formed of, for example, Flame Retardant Type 4 (FR4), which is a glass fiber reinforced epoxy resin substrate, or the like. In the example illustrated in FIG. 4, the printed wiring board 10 is a multilayer printed board, and L1 to L6 denotes respective wiring layers. The wiring layers L1 to L6 serve as transmission paths for various signals used for, for example, driving an electronic device. The wiring layers L1 to L6 are formed by, for example, patterning copper foil.

The memory packages 30 (30A and 30B) is semiconductor packages that include respective memory chips (storage elements) 300 therein. The memory chips (storage elements) 300 are, for example, synchronous dynamic random access memories (SDRAMs) or the like, which operate in synchronization with a system bus.

Hereafter, the memory package denoted by a reference sign 30A is referred to as a “first memory package” and the memory package denoted by a reference sign 30B is referred to as a “second memory package”. Here, the types (characteristics) of the memory chip 300 included in the first memory package 30A and the memory chip 300 included in the second memory package 30B are different from each other. In the present embodiment, vendors (manufacturers) of the first memory package 30A and the second memory package 30B are different from each other. That is, the wiring board unit 1 according to the present embodiment is a multi-vendor product, in which the memory packages 30 (the first memory package 30A and the second memory package 30B) manufactured by a plurality of manufacturers are mounted on the printed wiring board 10.

The memory controller (processor) 20 is a semiconductor package that includes a logic chip 200 such as an application specific integrated circuit (ASIC). Each of the memory chips 300 is connected to the logic chip 200 included in the memory controller 20 through a bus 102. As illustrated in FIG. 4, the bus 102 includes a main line 102A and branch lines 102B that branch off from the main line 102A. Through the bus 102 as described above, signals are sequentially transmitted from the logic chip 200 of the memory controller 20 to the plurality of memory chips 300 at time intervals. Such a configuration is called a daisy chain configuration. The daisy chain configuration may also be referred to as a fly-by configuration or a T-branch configuration, or sometimes compared to a potato vine.

In the wiring board unit 1 according to the present embodiment, various signals are sequentially transmitted from the memory controller 20 (logic chip 200) to the first memory chip 300 included in the first memory package 30A and the second memory chip 300 included in the second memory package 30B in this order.

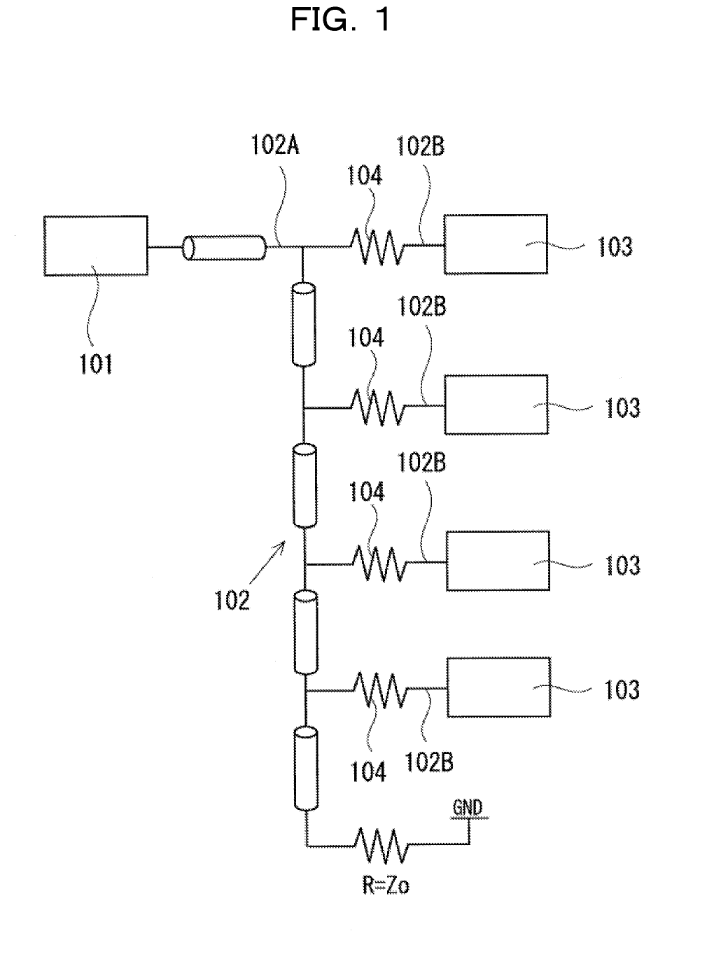

When signals are transmitted through the daisy chain configuration, as described with reference to FIG. 1, multipath reflections of the signals are superposed with one another, thereby disturbing the signal waveform. Insertion of stub resistors 104 in the branch lines 102B of a wiring board (see FIG. 1) are known as a method of reducing disturbance of the signal waveform. However, when the wiring board unit 1 is structured as a multi-vendor product as is the case with the present embodiment, it is considered to be difficult to improve the quality of the waveform of the signal transmitted from the memory controller 20 to the memory chips 300 and suppress signal delays. To address the above-described problem, in the wiring board unit 1 according to the present embodiment, the insertion bases 40 are interposed between the printed wiring board 10 and the memory packages 30A and 30B, which are electrically connected to the memory controller 20 through the daisy chain configuration. A detailed structure of the wiring board unit 1 are described below.

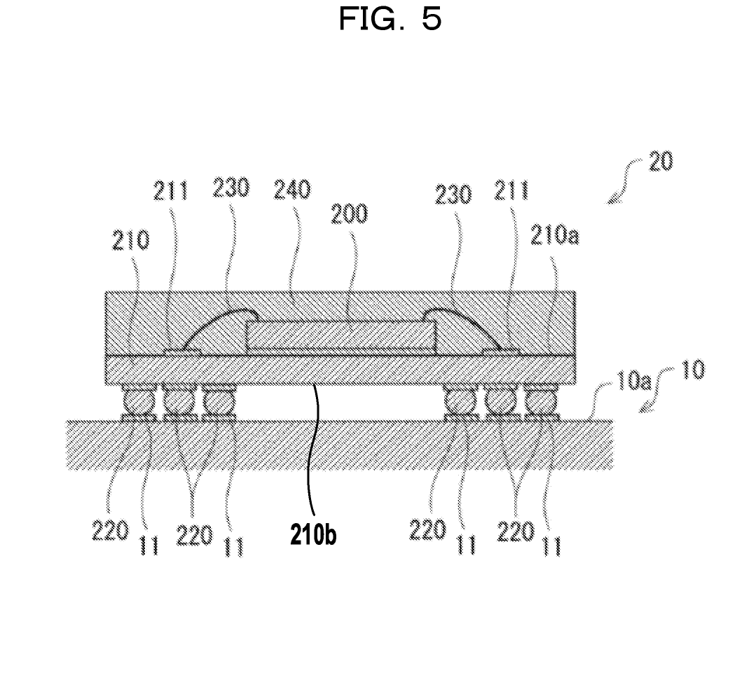

FIG. 5 illustrates a detailed structure of the memory controller 20 according to the embodiment. The memory controller 20 includes an interposer 210, which serves as a package board (support board). The logic chip 200 is mounted on the interposer 210. The logic chip 200 is mounted on an upper surface 210a of the interposer 210. A plurality of solder balls 220 as external terminals are provided on a lower surface 210b of the interposer 210.

The memory controller 20 further includes bonding wires 230, a sealing resin 240, and so forth. Electrode pads 211, which are formed on the upper surface 210a of the interposer 210, are connected to electrode pads (not illustrated), which are formed, for example, on a surface of the logic chip 200, through the bonding wires 230. The electrode pads 211 of the interposer 210 are electrically connected to the solder balls 220, which are formed on the lower surface 210b side, through holes or the like penetrating through the interposer 210. The logic chip 200 mounted on the interposer 210 is sealed with the sealing resin 240 such that the logic chip 200 is covered with the sealing resin 240. The sealing resin 240 may use, for example, a thermosetting epoxy resin or the like.

The wiring layer L1 is formed on an upper surface 10a of the printed wiring board 10. The wiring layer L1 includes board-side pads 11, which are formed of patterned copper foil. The board-side pads 11 are formed in a pattern so as to correspond to an arrangement pattern of the solder balls 220 of the memory controller 20 and soldered to the solder balls 220.

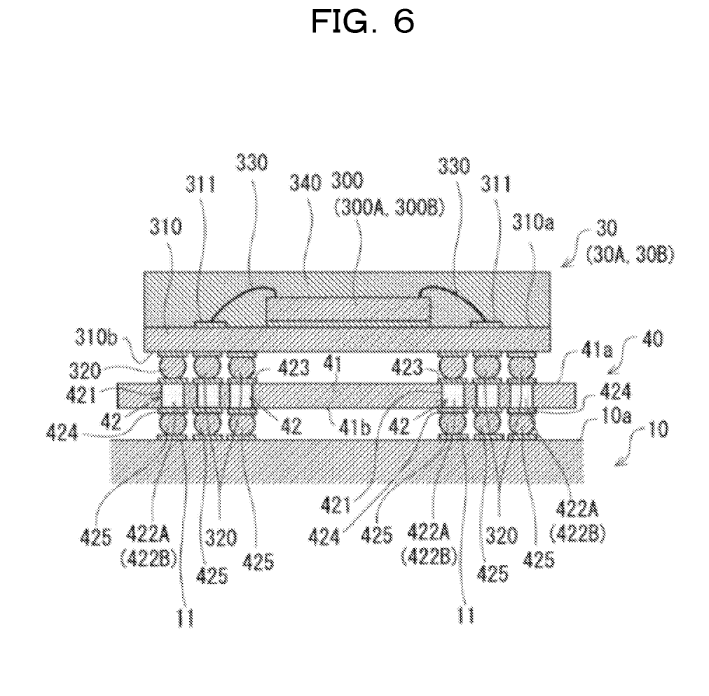

FIG. 6 illustrates a detailed structure of the memory package 30 (30A or 30B) and the insertion base 40. The memory package 30 (30A or 30B) include an interposer 310, which serves as a package board (support board). The memory chip 300 is mounted on the interposer 310. The memory chip 300 is mounted on an upper surface 310a of the interposer 310. A plurality of solder balls 320 as external terminals are provided on a lower surface 310b of the interposer 310.

The memory package 30 (30A or 30B) further include bonding wires 330, a sealing resin 340, and so forth. Electrode pads 311, which are formed on the upper surface 310a of the interposer 310, are connected to electrode pads (not illustrated), which are formed, for example, on a surface of the memory chip 300, through the bonding wires 330. The electrode pads 311 of the interposer 310 are electrically connected to the solder balls 320, which are formed on the lower surface 310b side, through holes or the like penetrating through the interposer 310. The solder balls 320 each serve as an example of an external terminal of the semiconductor package. The memory chip 300 mounted on the interposer 310 is sealed with the sealing resin 340 such that the memory chip 300 is covered with the sealing resin 340. The sealing resin 340 may use, for example, a thermosetting epoxy resin or the like.

The board-side pads 11 of the printed wiring board 10 are formed in a pattern so as to match to an arrangement pattern of each of the solder balls 320 formed on the memory package 30 (30A or 30B). That is, the pattern of the board-side pads 11 of the printed wiring board 10 are formed so that the board-side pads 11 are superposed with the solder balls 320 on the memory package 30 (30A or 30B) side in the up and down direction. The board-side pads 11 of the printed wiring board 10 are soldered to the solder balls 320.

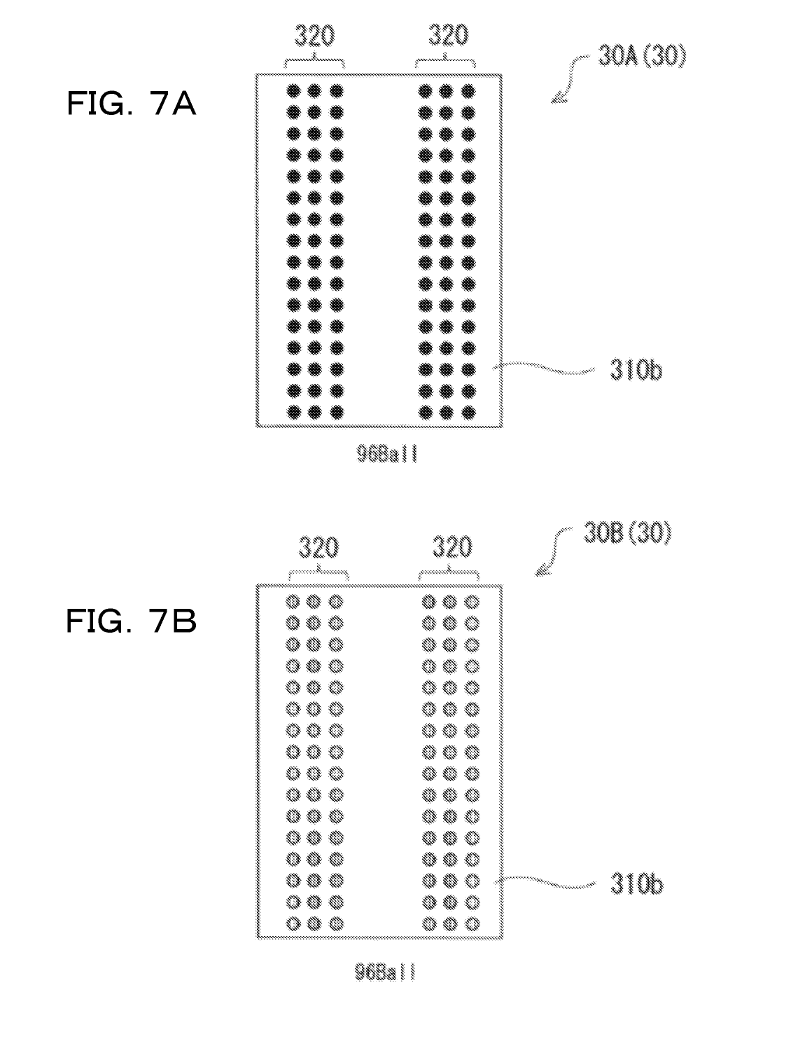

FIGS. 7A and 7B respectively illustrate the arrangement patterns of the solder balls 320 in the memory packages 30A and 30B. FIG. 7A illustrate the lower surface 310b of the first memory package 30A, and FIG. 7B illustrate the lower surface 310b of the second memory package 30B. As illustrated in FIGS. 7A and 7B, the arrangement patterns (planar layouts) of the solder balls 320 in the first memory package 30A and the second memory package 30B are the same.

Next, a detailed structure of the insertion base 40 is described. Referring to FIG. 6, the insertion base 40 is inserted between the printed wiring board 10 and the memory package 30 (30A or 30B). The insertion base 40 includes a base material 41 and a plurality of connection portions 42 provided in the base material 41. The base material 41 of the insertion base 40 is formed of, for example, FR4 (a glass fiber reinforced epoxy resin substrate) or the like. The connection portions 42 each have a through hole 421 penetrating through the base material 41 and a resistance material 422A (or a low resistance material 422B) with which the through hole 421 is filled. As will be described later, the resistance material 422A and the low resistance material 422B are electrically conductive. The resistance of the resistance material 422A is higher than that of the low resistance material 422B.

Package coupling pads 423 are formed on an upper surface 41a of the base material 41 corresponding to the respective through holes 421. Board coupling pads 424 are formed on a lower surface 41b of the base material 41 corresponding to the respective through holes 421. The package coupling pads 423 are electrically connected to upper surfaces of the resistance material 422A (or low resistance material 422B). The board coupling pads 424 are electrically connected to lower surfaces of the resistance material 422A (or low resistance material 422B). A solder ball 425 that serves as an external terminal is formed on each of the board coupling pads 424 of the insertion base 40. The board coupling pads 424 are connected to the board-side pads 11 of the printed wiring board 10 through the solder balls 425. The solder balls 425 are each coupled to a corresponding one of the board-side pads 11. The plurality of connection portions 42 (the resistance material 422A or the low resistance material 422B) of the insertion base 40 each electrically connect a corresponding one of the board-side pads 11 of the printed wiring board 10 and a corresponding one of the solder balls 320 of the memory package 30 (30A or 30B) to one another.

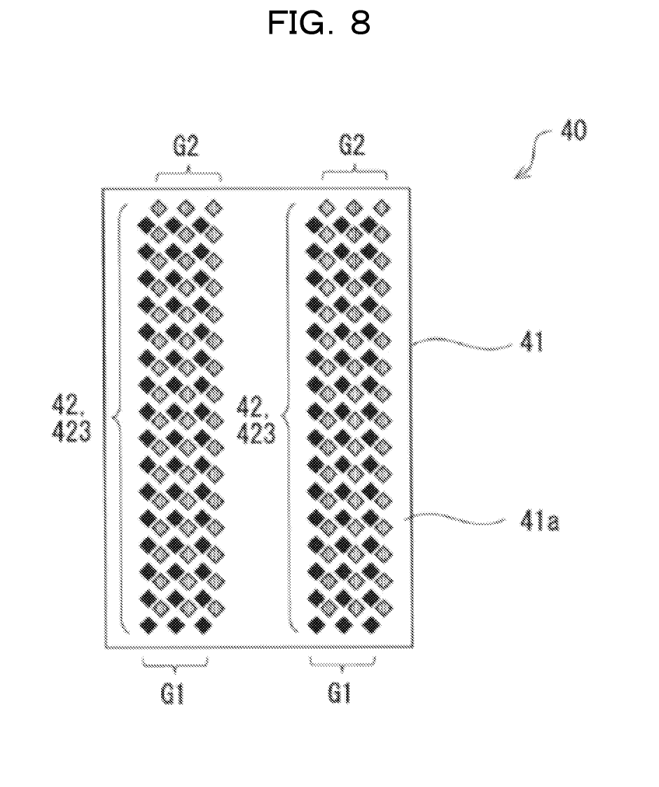

FIG. 8 illustrates an arrangement pattern (planar layout) of the connection portions 42 of the insertion base 40 in the upper surface 41a of the insertion base 40. As illustrated in FIG. 8, the plurality of connection portions 42 formed in the insertion base 40 each belong to either of a group of the connection portions 42 represented by solid rhombuses in FIG. 8 and a group of the connection portions 42 represented by hatched rhombuses in FIG. 8. Hereafter, the group of the connection portions 42 represented by the solid rhombuses is referred to as a “first connection portion group G1” and the group of the connection portions 42 represented by the hatched rhombuses is referred to as a “second connection portion group G2”. The plurality of groups of the connection portions 42 (the first connection portion group G1 and the second connection portion group G2) are arranged in the insertion base 40.

The first connection portion group G1 and the second connection portion group G2 are selectively used in accordance with (so as to match) the type (characteristics) of the memory chip 300 included in the memory package 30 (30A or 30B) when connecting the board-side pads 11 to the solder balls 320. Here, it is assumed that, for convenience, the vendor (manufacturer) of the first memory package 30A is vendor A and the vendor of the second memory package 30B is vendor C. The arrangement pattern (planar layout) of the first connection portion group G1 corresponds to the arrangement pattern (planar layout) of the solder balls 320 of the first memory package 30A manufactured by vendor A. The arrangement pattern (planar layout) of the second connection portion group G2 corresponds to the arrangement pattern (planar layout) of the solder balls 320 in the second memory package 30B manufactured by vendor C. Since the arrangement pattern of the solder balls 320 of the first memory package 30A is the same as that of the second memory package 30B in the present embodiment, the arrangement pattern of the first connection portion group G1 is the same as that of the second connection portion group G2. When the first connection portion group G1 and the second connection portion group G2 are not particularly distinguished, they may be collectively referred to as “connection portion groups G”.

When the first memory package 30A manufactured by vendor A is mounted on the printed wiring board 10, the first connection portion group G1 of the insertion base 40 is selectively used. That is, the board-side pads 11 of the printed wiring board 10 and the solder balls 320 of the memory package 30 are electrically connected to one another through the first connection portion group G1. More specifically, the solder balls 425 and the package coupling pads 423 of the connection portions 42 (solid) included in (belonging to) the first connection portion group G1 are respectively soldered to the board-side pads 11 and the solder balls 320. In this case, the second connection portion group G2 of the insertion base 40, which is inserted (interposed) between the first memory package 30A and the printed wiring board 10, is not used.

When the second memory package 30B manufactured by vendor C is mounted on the printed wiring board 10, the second connection portion group G2 is selectively used. That is, the board-side pads 11 of the printed wiring board 10 and the solder balls 320 of the memory package 30 are electrically connected to one another through the second connection portion group G2. More specifically, the solder balls 425 and the package coupling pads 423 of the connection portions 42 (hatched) included in (belonging to) the second connection portion group G2 are respectively soldered to the board-side pads 11 and the solder balls 320. In this case, the first connection portion group G1 of the insertion base 40, which is inserted (interposed) between the second memory package 30B and the printed wiring board 10, is not used.

In the present embodiment, the resistances R of the connection portions 42 included in the first connection portion group G1 and the second connection portion group G2 of the insertion base 40 are adjusted in accordance with the types of the target memory chips 300. Hereafter, the memory chip 300 included in the first memory package 30A is referred to as a “first memory chip 300A”, and the memory chip 300 included in the second memory package 30B is referred to as a “second memory chip 300B”.

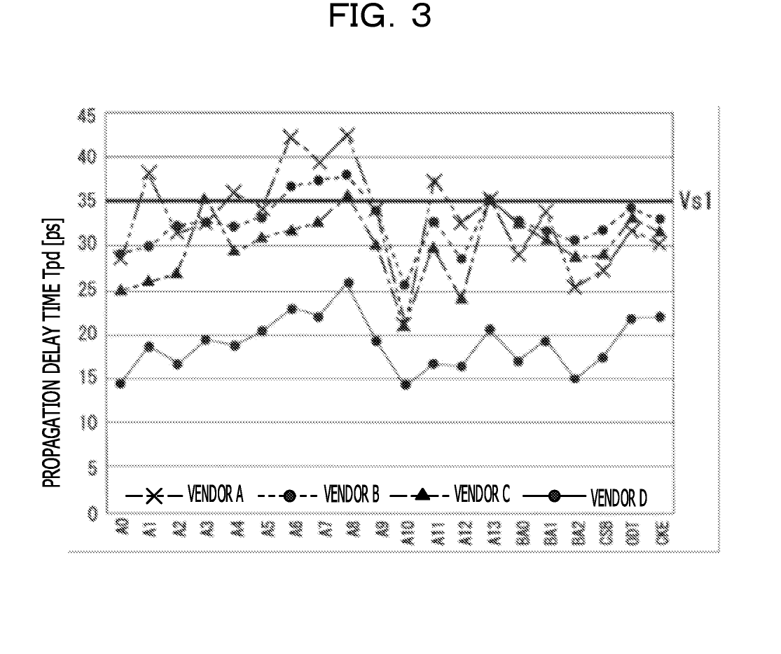

Referring to FIG. 3, a line denoted by a reference sign Vs1 represents a determination reference value (threshold value), the vertical axis represents propagation delay time, and the types of signals transmitted from the memory controller 20 through the bus 102 are arranged along the horizontal axis. The determination reference value Vs1 in FIG. 3 is a propagation delay time that serves as a threshold value to determine whether or not insertion of a stub resistor in the branch line 102B is desirable for a signal transmitted to the memory packages 30 (memory chips 300) manufactured by the vendors.

In the present embodiment, whether or not the propagation delay time exceeds the determination reference value Vs1 is checked in advance for each of the types of the signals transmitted to the memory chips 300. Thus, it may be determined that, for example, improvement of the quality of the signal waveform and signal delay is desirable for a signal, the propagation delay time of which exceeds the determination reference value Vs1. Thus, for signals, the propagation delay times of which exceed the determination reference value Vs1, the resistance material 422A is disposed in the corresponding connection portions 42 of the insertion base 40. The resistance material 422A is used as so-called stub resistors. The low resistance material 422B is disposed in the other connection portions 42, that is, the connection portions 42 that correspond to signals, the propagation delay times of which are equal to or smaller than the determination reference value Vs1. Instead of disposing the low resistance material 422B, the connection portions 42 may be each formed as a through hole. This through hole is formed by, for example, plating an inner wall surface of the through hole 421 that penetrates through the base material 41. The board coupling pads 424 and the package coupling pads 423 are electrically connected to one another through the plated surfaces.

Next, referring to FIG. 3, cases with vendor A and vendor C are described with specific examples. Regarding the first memory chip 300A of vendor A, the propagation delay times corresponding to signals A1, A4, A6 to A8, A11, and A13 exceed the determination reference value Vs1. Accordingly, out of the connection portions 42 included in the first connection portion group G1 of the insertion base 40, the resistance material 422A is disposed in the connection portions 42 through which signals corresponding to A1, A4, A6 to A8, A11, and A13 are transmitted, and the low resistance material 422B is disposed in the other connection portions 42. The resistance material 422A and the low resistance material 422B are electrically conductive. The resistance R of the resistance material 422A is adjusted so that the resistance R of the resistance material 422A is higher than that of the low resistance material 422B. As will be described later, in the present embodiment, the resistance material 422A is formed of a solidified carbon paste and the low resistance material 422B is formed of a solidified silver paste. However, the materials of the resistance material 422A and the low resistance material 422B are not limited to these. The electrically conductive paste that forms the resistance material 422A may be a nickel paste instead of the carbon paste. In general, the volume resistivity ρ of the carbon paste is about 0.13Ω·cm, and the volume resistivity ρ of the nickel paste is about 0.27Ω·cm. In general, by tuning (adjusting the grain size, shape, and content of) the above-described resistance materials, the volume resistivity ρ of the resistance materials are adjustable in a range from about 0.5 to about 2.0 times the above-described values.

Here, in an example illustrated in FIG. 3, regarding the second memory chip 300B of vendor C, the propagation delay times corresponding to the signals A3, A8, and A13 exceed the determination reference value Vs1. Accordingly, out of the connection portions 42 included in the second connection portion group G2 of the insertion base 40, the resistance material 422A is disposed in the connection portions 42 corresponding to the signals A3, A8, and A13, and the low resistance material 422B is disposed in the other connection portions 42.

Next, the resistance R of the resistance material 422 disposed in the connection portions 42 of the insertion base 40 is described. The resistance R of the resistance material 422A disposed in the connection portions 42 is set as follows: R=Zo/2, that is, a value half a wiring impedance Zo of the main line 102A of the bus 102. For example, assuming that the main line 102A, through which the signal A1 is transmitted, is formed in the wiring layer L1 of the printed wiring board 10, and the wiring impedance Zo of the main line 102A formed in the wiring layer L1 is 60Ω. In this case, out of the connection portions 42 (resistance connection portions) belonging to the first connection portion group G1 of the insertion base 40, the resistance R of the resistance material 422A is adjusted to 30Ω in the connection portion 42 corresponding to the signal A1.

For example, assuming that the main line 102A, through which the signal A8 is transmitted, is formed in the wiring layer L3 of the printed wiring board 10, and the wiring impedance Zo of the main line 102A formed in the wiring layer L3 is 40Ω. In this case, out of the connection portions 42 belonging to the first connection portion group G1 and the second connection portion group G2 of the insertion base 40, the resistance R of the resistance material 422A is adjusted to 20Ω in the connection portions 42 corresponding to the signal A8.

Regarding the first connection portion group G1, the resistance R of the resistance material 422A is adjusted to half the wiring impedance Zo of the corresponding main line 102A also in the connection portions 42 corresponding to the signals A4, A6, A7, A11, and A13, the propagation delay times of which exceeds the determination reference value Vs1. Likewise, regarding the second connection portion group G2, the resistance R of the resistance material 422A is adjusted to half the wiring impedance Zo of the corresponding main line 102A also in the connection portions 42 corresponding to the signals A3 and A13. As described above, for each of the first connection portion group G1 and the second connection portion group G2 of the insertion base 40, the resistance R of the resistance material 422A in the resistance connection portions 42 is adjusted in accordance with the value of the wiring impedance of the main line 102A.

Here, the resistance R of the resistance material 422A may be calculated by the following expression 1, where the volume resistivity ρ in Ω·cm of the resistance material 422A, the thickness L in cm of the resistance material 422A, and the sectional area A cm² of the resistance material 422A are parameters:

Resistance R=ρ×L/A 1

Here, the thickness L of the resistance material 422A is the same as the thickness of the base material 41, and the sectional area A of the resistance material 422A is the same as the sectional area of the through hole 421. Thus, assuming that the thickness of the base material 41 is fixed, by adjusting the volume resistivity ρ of the material of the resistance material 422A and the sectional area of the through hole 421 that penetrates through the base material 41, the resistance R of the resistance material 422A may be adjusted. For example, when the thickness of the base material 41 is 200 μm and the diameter of the through hole 421 is 200 μm, the resistance R may be adjusted to 30Ω by setting the volume resistivity ρ of the resistance material 422A to be used to 0.47 Ω·cm. Also, under the same conditions for the base material 41, by setting the volume resistivity ρ of the resistance material 422A to 0.31 Ω·cm, the resistance R may be adjusted to 20Ω. The resistance R may be alternatively adjusted by changing the diameter of the through hole 421 instead of changing the volume resistivity ρ of the resistance material 422A. The resistance R may be increased by reducing the diameter of the through hole 421 that penetrates through the base material 41, and the resistance R may be reduced by increasing the diameter of the through hole 421.

Manufacturing Method

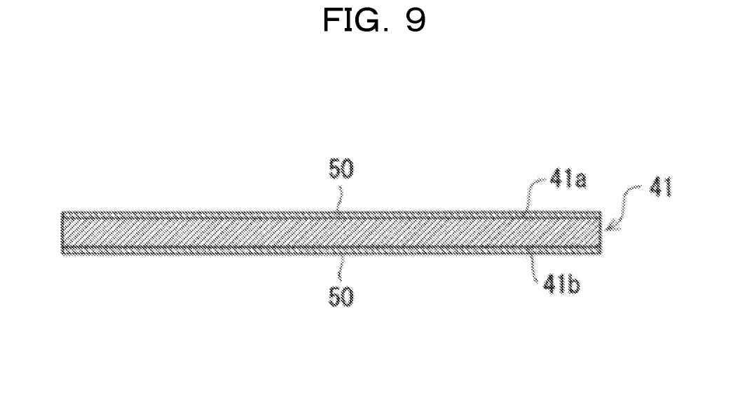

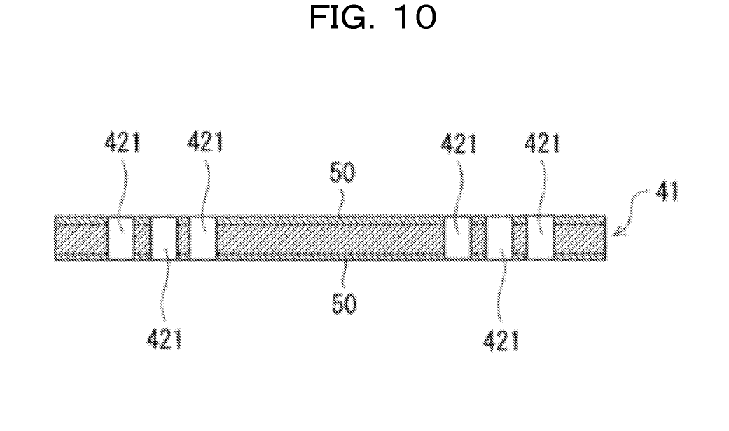

Next, a method of manufacturing the insertion base 40 and a method of manufacturing the wiring board unit 1 according to the present embodiment are described. Initially, as illustrated in FIG. 9, the base material 41 of the insertion base 40 is prepared, and polyethylene terephthalate (PET) films 50 are bonded to both surfaces of the base material 41. After that, as illustrated in FIG. 10, the through holes 421 are formed in the base material 41, to which the PET films 50 have been bonded. The base material 41 may use a prepreg formed of a glass fiber reinforced epoxy resin. The formation of the through holes 421 in the base material 41 may be performed by, for example, laser beam machining or the like. In the flat surface of the base material 41, the through holes 421 are formed so as to match the arrangement pattern of the solder balls 320 of the first memory package 30A and the arrangement pattern of the solder balls 320 of the second memory package 30B.

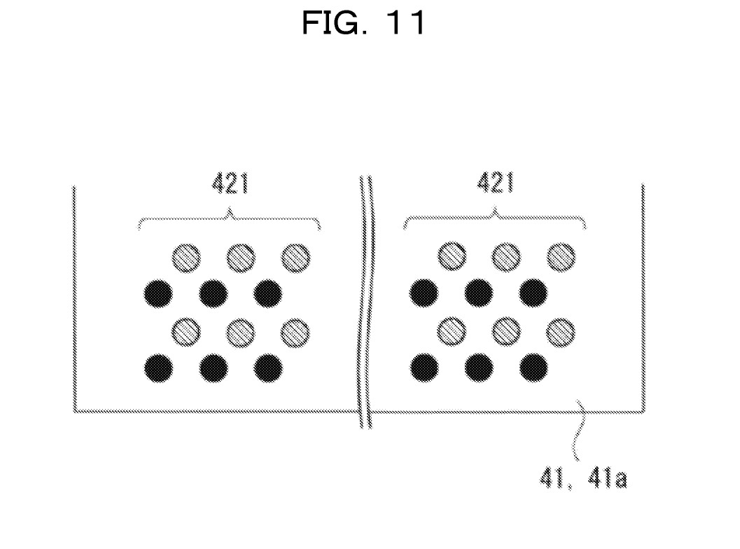

As illustrated in FIG. 11, the through holes 421 corresponding to the solder balls 320 of the first memory package 30A (represented by solid circles in FIG. 11) are arranged at positions shifted in the arrangement direction from positions where the through holes 421 corresponding to the solder balls 320 of the second memory package 30B (represented by hatched circles in FIG. 11) are arranged. Thus, the through holes 421 formed in the base material 41 are generally arranged in a staggered pattern. It is noted that FIG. 11 is an enlarged view schematically illustrating part of the upper surface 41a of the base material 41.

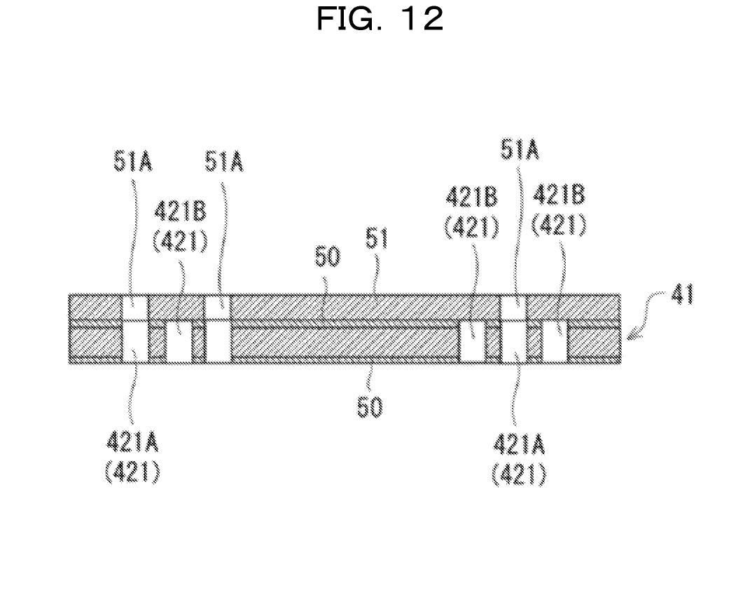

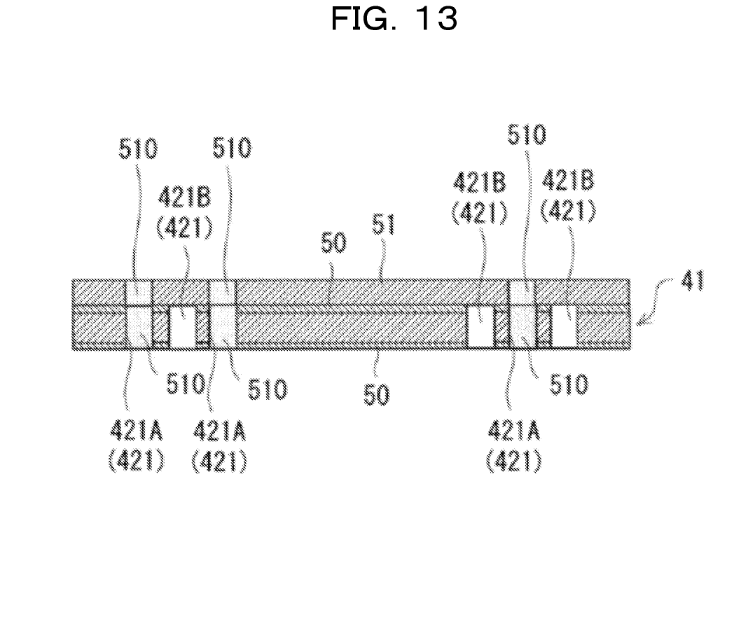

Out of the plurality of through holes 421 formed in the base material 41, the through holes corresponding to the connection portions 42 where the resistance material 422A is disposed are referred to as “first through holes 421A” and the through holes corresponding to the connection portions 42 where the low resistance material 422B is disposed are referred to as “second through holes 421B”. As illustrated in FIG. 12, a first metal mask 51 is disposed on the base material 41. Openings 51A are formed in a pattern in the first metal mask 51 so that the openings 51A are formed at positions corresponding to the first through holes 421A. Carbon paste 510 is supplied so as to form the resistance material 422A on the first metal mask 51 and is caused to flow into the openings 51A by using a squeegee. As a result, the first through holes 421A are filled with the carbon paste 510 flowing through the openings 51A formed in the first metal mask 51 (see FIG. 13).

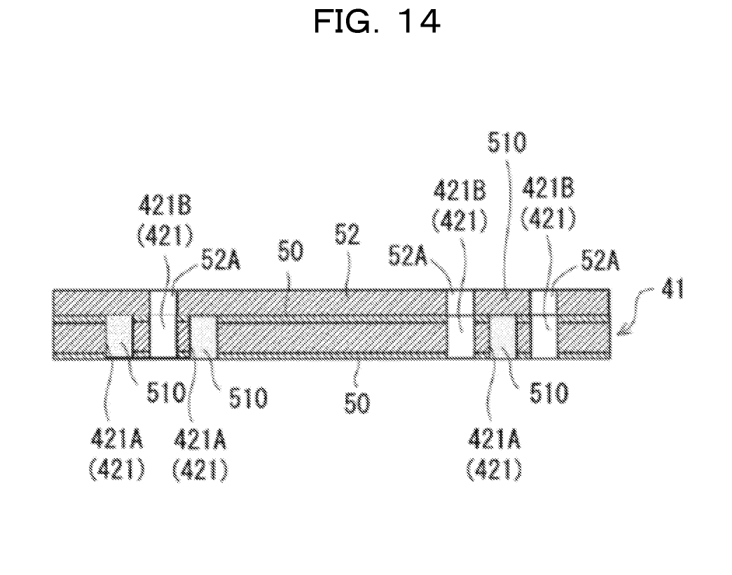

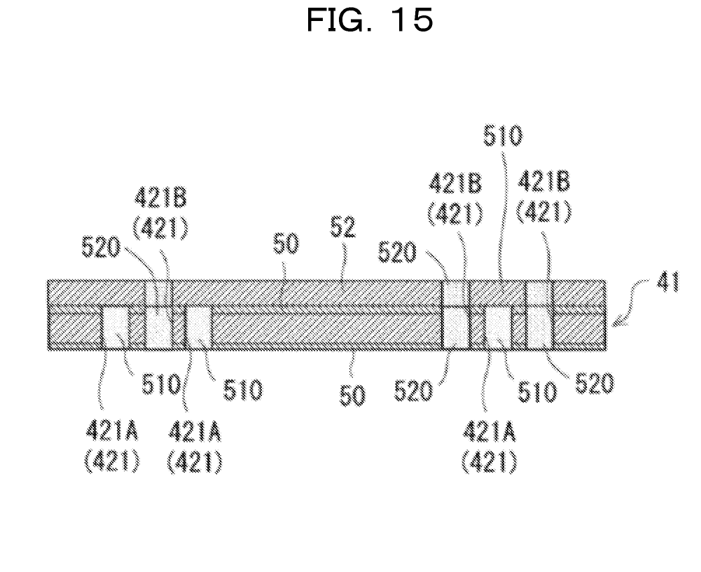

Next, the first metal mask 51 is removed from the base material 41, and, as illustrated in FIG. 14, a second metal mask 52 is disposed on the base material 41. Openings 52A are formed in a pattern in the second metal mask 52 so that the pattern of the openings 52A matches the arrangement pattern of the second through holes 421B. Silver paste 520 is supplied so as to form the low resistance material 422B on the second metal mask 52 and is caused to flow into the openings 52A by using a squeegee. As a result, the second through holes 421B are filled with the silver paste 520 flowing through the openings 52A formed in the second metal mask 52 (see FIG. 15).

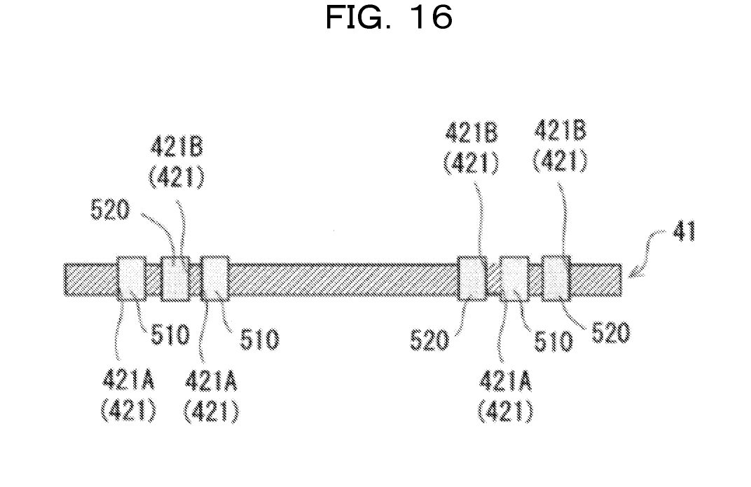

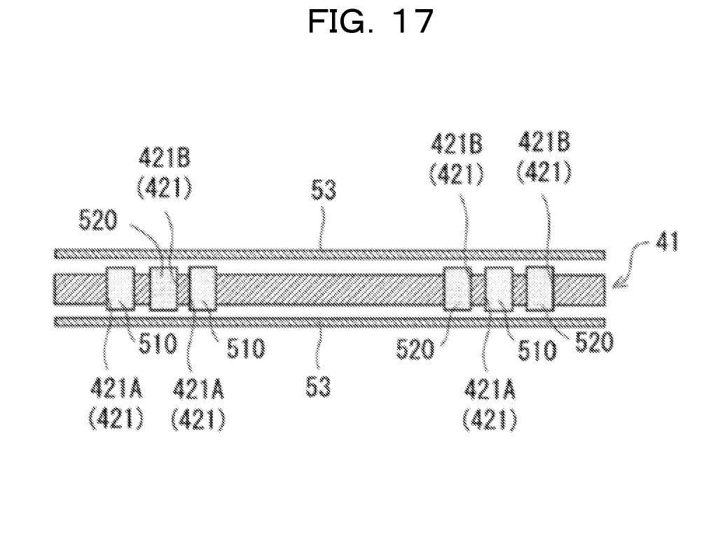

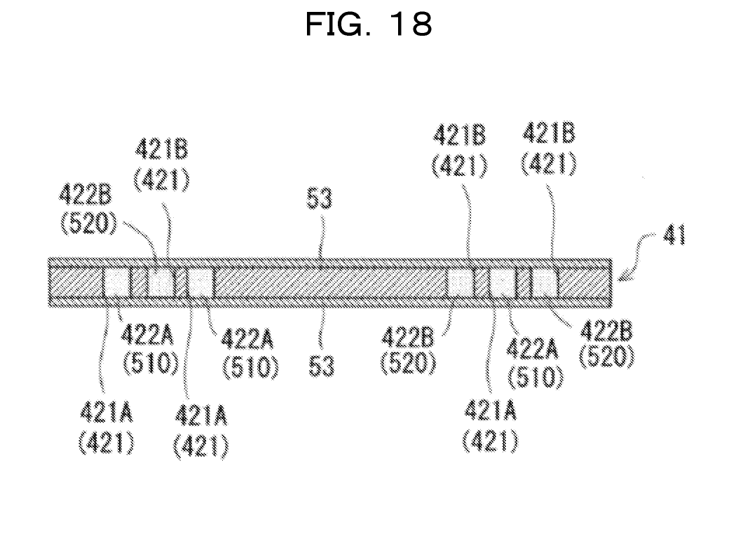

Next, the second metal mask 52 is removed from the base material 41, and, as illustrated in FIG. 16, the PET films 50 are removed from the base material 41. Next, as illustrated in FIG. 17, copper foil 53 is stacked on both the surfaces of the base material 41, and the resultant structure is subjected to a vacuum hot-pressing treatment. Through the vacuum hot-pressing treatment performed as described above on the carbon paste 510, with which the first through holes 421A are filled, and the silver paste 520, with which the second through holes 421B are filled, the carbon paste 510 and the silver paste 520 are solidified. Both the carbon paste 510 and the silver paste 520 are electrically conductive. The volume resistivity ρ of the carbon paste 510 is higher than that of the silver paste 520. As a result, as illustrated in FIG. 18, the resistance material 422A is formed of the solidified carbon paste 510 and the low resistance material 422B is formed of the solidified silver paste 520.

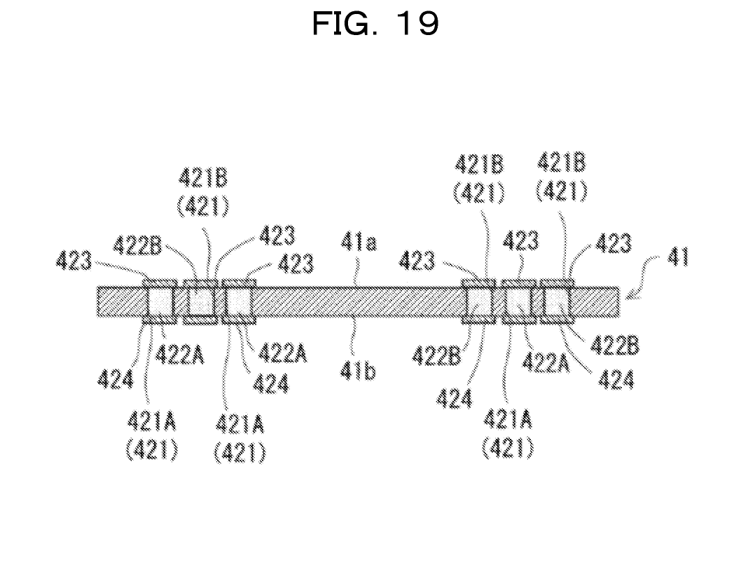

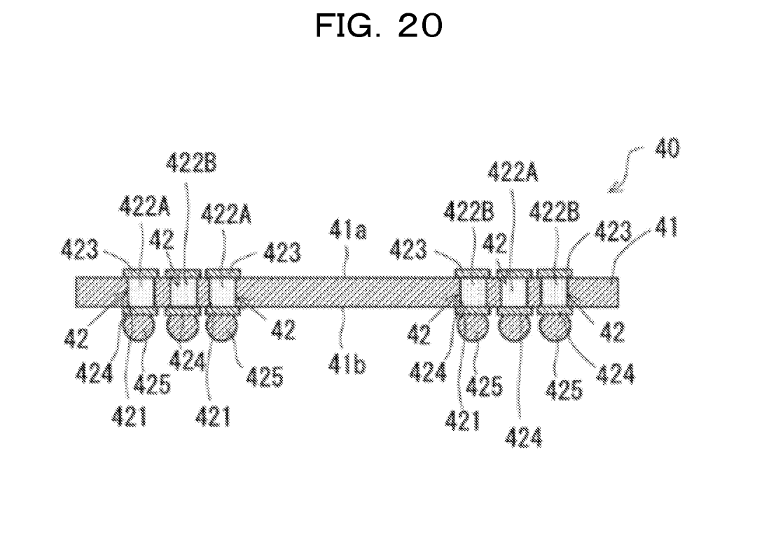

Next, the copper foil stacked on the surfaces of the base material 41 is etched to form patterns. That is, as illustrated in FIG. 19, the package coupling pads 423 are formed in a pattern in the upper surface 41a of the base material 41 and the board coupling pads 424 are formed in a pattern in the lower surface 41b of the base material 41. Next, as illustrated in FIG. 20, the solder balls 425 are attached to the board coupling pads 424. Thus, the connection portions 42 that each include the package coupling pad 423, the resistance material 422A (or low resistance material 422B), the board coupling pad 424, and the solder ball 425 are formed. Through the above-described process, the insertion base 40 according to the present embodiment is obtained.

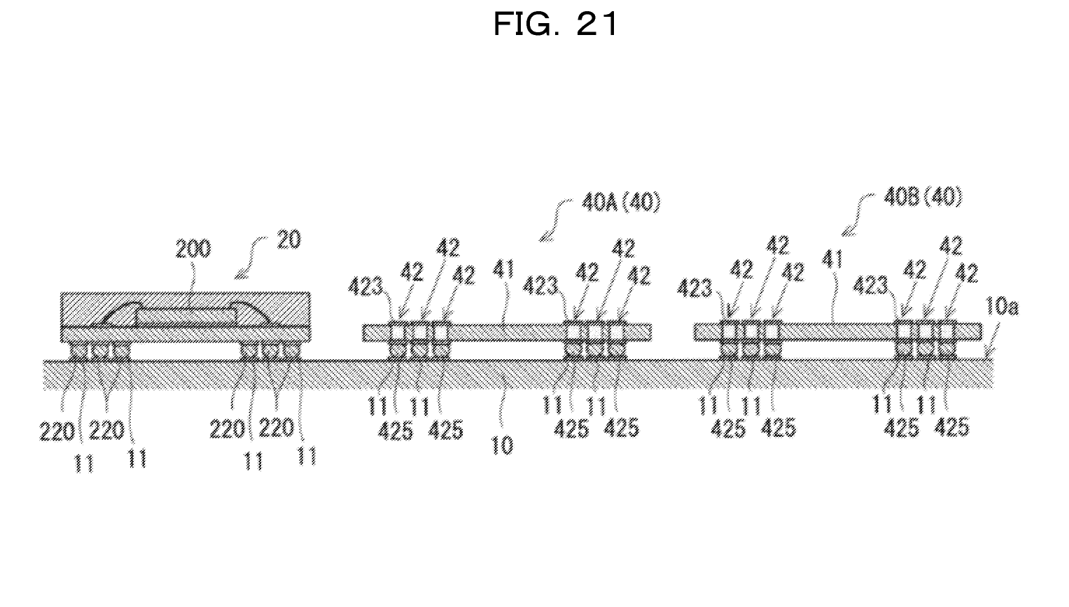

Next, the method of manufacturing the wiring board unit 1 using the insertion bases 40 formed as described above is described. The memory controller 20, the first memory package 30A, and the second memory package 30B, which are to be mounted on the printed wiring board 10, and the printed wiring board 10 are prepared. Since the printed wiring board 10 is a usual multilayer printed wiring board, detailed description of manufacturing process of the printed wiring board 10 is omitted. Solder paste is transferred onto the board-side pads 11 formed on the upper surface 10a of the printed wiring board 10. After that, the memory controller 20 and the insertion bases 40 are placed on the board-side pads 11, and the resultant structure is heated in a reflow oven. Thus, as illustrated in FIG. 21, the memory controller 20 and the insertion bases 40 have been mounted on the printed wiring board 10.

The insertion bases 40 are mounted on the printed wiring board 10 by soldering the solder balls 425 of the insertion base 40 and the board-side pads 11 of the printed wiring board 10 to one another. Here, the insertion base inserted between the first memory package 30A and the printed wiring board 10 is referred to as a “first insertion base 40A”. In the first insertion base 40A, out of the first and second connection portion groups G1 and G2, the first connection portion group G1 is selected and used (see FIG. 8). That is, in the first insertion base 40A, the solder balls 425 of the connection portions 42 belonging to the first connection portion group G1 are soldered to the board-side pads 11. The insertion base inserted between the second memory package 30B and the printed wiring board 10 is referred to as a “second insertion base 40B”. In the second insertion base 40B, out of the first and second connection portion groups G1 and G2, the second connection portion group G2 is selected and used (see FIG. 8). That is, in the second insertion base 40B, the solder balls 425 of the connection portions 42 belonging to the second connection portion group G2 are soldered to the board-side pads 11.

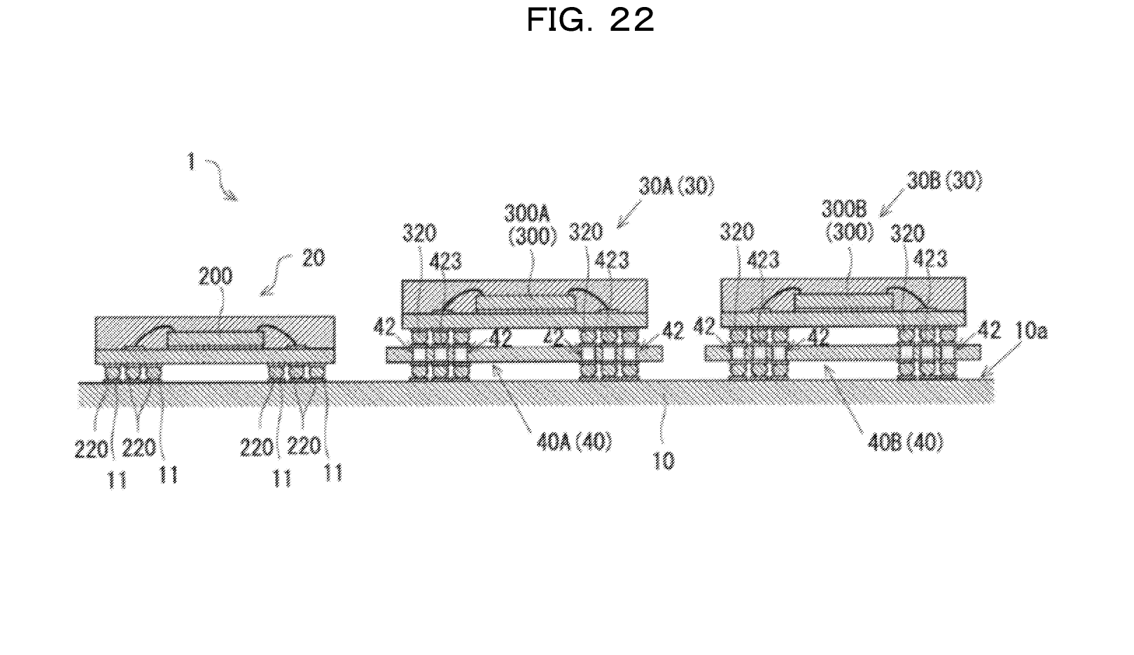

Next, solder paste is supplied onto the package coupling pads 423 corresponding to the first connection portion group G1 of the first insertion base 40A and the package coupling pads 423 corresponding to the second connection portion group G2 of the second insertion base 40B. Next, as illustrated in FIG. 22, the first memory package 30A and the second memory package 30B are placed on the package coupling pads 423 of the first insertion base 40A and the second insertion base 40B, onto which the solder paste has been transferred, and the resultant structure is heated in the reflow oven.

As a result, the solder balls 320 of the first memory package 30A are soldered to the package coupling pads 423 of the connection portions 42 that correspond to the first connection portion group G1 (see FIG. 8) of the first insertion base 40A. Likewise, the solder balls 320 of the second memory package 30B are soldered to the package coupling pads 423 of the connection portions 42 that correspond to the second connection portion group G2 (see FIG. 8) of the second insertion base 40B. Thus, the first memory package 30A and the second memory package 30B have been mounted on the printed wiring board 10, and the manufacturing process of the wiring board unit 1 is completed (see FIG. 22).

As described above, each of the insertion bases 40 according to the present embodiment includes the plurality of connection portion groups G1 and G2 that are suitable for the memory packages 30 including the memory chips 300 of different types (characteristics). The suitable connection portion group G1 or G2 is selected in accordance with the type of the memory package 30 (memory chip 300) to be mounted. The board-side pads 11 of the printed wiring board 10 and the solder balls 320 of the memory package 30 are connected to one another through the selected connection portion group.

The insertion bases 40 and the wiring board unit 1 according to the present embodiment produce the following effects. In the first insertion base 40A on which, for example, the first memory package 30A manufactured by vendor A is mounted, the first connection portion group G1 suitable for the characteristics of the first memory chip 300A may be selected. This allows the resistances R of the connection portions 42 corresponding to the signals transmitted to the first memory chip 300A to be desirably adjusted in accordance with the characteristics of the first memory chip 300A. Thus, the quality of the signal waveform may be improved and signal delays may be suppressed. In the second insertion base 40B on which the second memory package 30B manufactured by vendor C is mounted, the second connection portion group G2 suitable for the characteristics of the second memory chip 300B may be selected. This allows the resistances R of the connection portions 42 corresponding to the signals transmitted to the second memory chip 300B to be desirably adjusted in accordance with the characteristics of the second memory chip 300B. Thus, the quality of the signal waveform may be improved and signal delays may be suppressed.

The insertion base 40 includes the plurality of connection portion groups G, the resistances of which are adjusted so as to be suitable for the plurality of memory chips 300 having characteristics different from one another. Thus, the desirable quality of the signal waveform may be ensured and the signal delays may be suppressed without depending on the vendors that manufacture the memory chips 300. That is, when the memory chips 300 mounted on the wiring board unit 1 is manufactured by multiple vendors, it may be easy to ensure the quality of the signal waveform and suppress signal delays. In so doing, since the stub resistors are not directly disposed on the wiring board, a routing topology of the wiring board is not affected.

When, for example, the first memory package 30A coupled to the first insertion base 40A is replaced with the second memory package 30B in rework, the rework may be easily performed without affecting the routing topology of the printed wiring board 10. In this case, it is sufficient that the first memory package 30A be removed from the first insertion base 40A and the second memory package 30B be soldered using the second connection portion group G2. Since the resistances of the connection portions 42 corresponding to (belonging to) the second connection portion group G2 are adjusted in accordance with the characteristics of the second memory chip 300B, the desirable quality of the signal waveform may be obtained and signal delays are suppressed after the rework.

In the present embodiment, the memory chips 300 having characteristics different from each other are manufactured by the different vendors. However, the characteristics of the memory chips manufactured by a single vendor may vary when the model numbers of the memory chips are different from one another. When the memory chips 300 of different model numbers are mounted as described above, the insertion bases 40 according to the present embodiment is useful. For example, it is desirable that the first connection portion group G1 and the second connection portion group G2 be formed in each of the insertion bases 40 so as to be suitable for the respective memory chips 300, the model numbers of which are different from one another. Thus, when the memory chips 300, the model numbers of which are different from one another, are mounted on a single wiring board unit 1, or when rework is performed so as to replace the memory chip 300 with another memory chip 300 of a different model number, the quality of the signal waveform may be improved and signal delays may be suppressed without changing the routing topology of the printed wiring board 10.

In the flat surface of the base material 41 of the insertion base 40, the connection portions 42 included in the first connection portion group G1 are arranged at positions shifted in the arrangement direction from positions where the connection portions 42 included in the second connection portion group G2 are arranged, and the plurality of connection portions 42 are generally arranged in a staggered pattern (see, for example, FIGS. 8 and 11). Thus, the plurality of connection portion groups G, which correspond to (are suitable for) the respective memory chips of different types, may be formed in the flat surface of the base material 41 without excessively enlarging a mounting region of the insertion base 40. That is, the size of the insertion base 40 may be reduced.

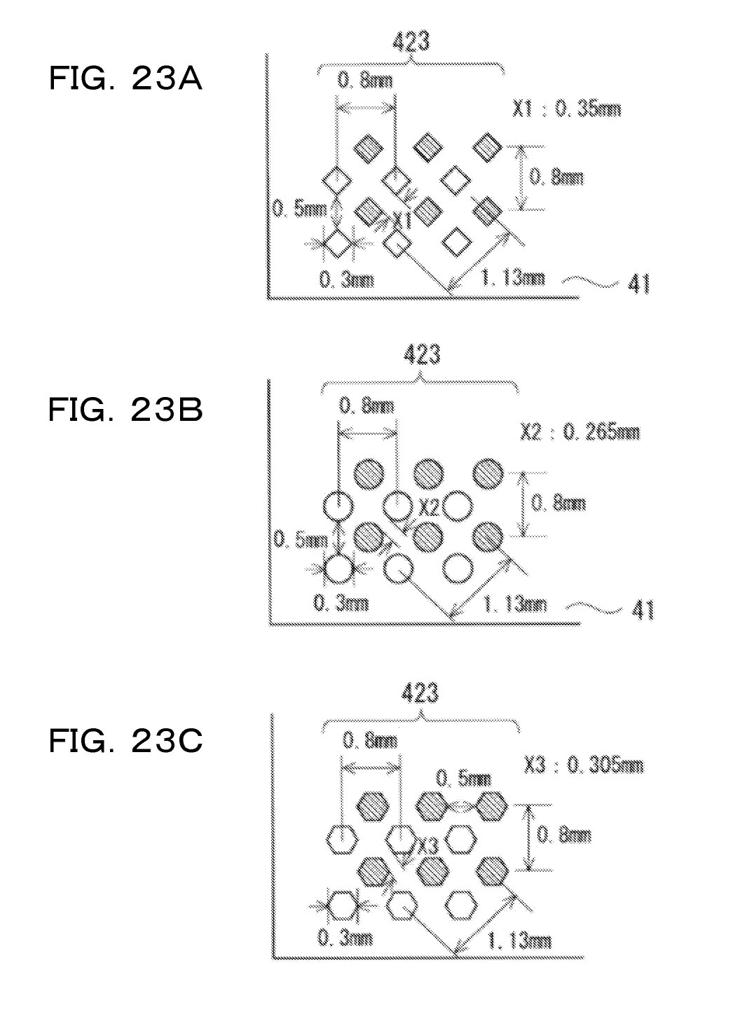

Although the planar shape (pad shape) of the package coupling pads 423 (board coupling pads 424) formed in the insertion base 40 is a rhombus in the present embodiment, the shape of the package coupling pads 423 (board coupling pads 424) is not limited to this and may be formed into any of a various shapes as illustrated in FIGS. 23A to 23C. That is, other than the rhombus illustrated in FIG. 23A, the package coupling pads 423 (board coupling pads 424) may have a circular shape as illustrated in FIG. 23B or a hexagonal shape as illustrated in FIG. 23C. In FIGS. 23A to 23C, part of the upper surface 41a of the insertion base 40 is illustrated. The package coupling pads 423 corresponding to the first connection portion group G1 are referred to as “first pads” and represented by hollow shapes. The package coupling pads 423 corresponding to the second connection portion group G2 are referred to as “second pads” and represented by hatched shapes.

Referring to FIGS. 23A to 23C, the pitch of the first pads and the pitch of the second pads are set to 0.8 mm. In the rhombus pads illustrated in FIG. 23A, the length of the diagonal line of each pads is set to 0.3 mm. For such rhombus pads, it is ensured that first and second pads are spaced apart from one another with gaps of 0.35 mm therebetween. Next, in the circular pads illustrated in FIG. 23B, the diameter φ of each pads is set to 0.3 mm. For such circular pads, it is ensured that the first and second pads are spaced apart from one another with gaps of 0.265 mm therebetween. Next, in the hexagonal pads illustrated in FIG. 23C, the distance between opposing apexes is set to 0.3 mm. For such hexagonal pads, it is ensured that first and second pads are spaced apart from one another with gaps of 0.305 mm therebetween. As described above, when the rhombus pads illustrated in FIG. 23A or the hexagonal pads illustrated in FIG. 23C are used, it is ensured that clearances set between the first and second pads may be increased compared to that in the case where the circular pads illustrated in FIG. 23B are used. In the above-described examples, when the rhombus pads are used, it is ensured that largest clearances may be set between the first and second pads. Despite this, the pad shape is not limited to the above-described variations and the pads may have any of various shapes.

In the insertion base 40 according to the present embodiment, two connection portion groups G (first connection portion group G1 and the second connection portion group G2), which are selectively used in accordance with the type of the memory chip 300, are formed in the base material 41. However, three or more connection portion groups G may be formed.

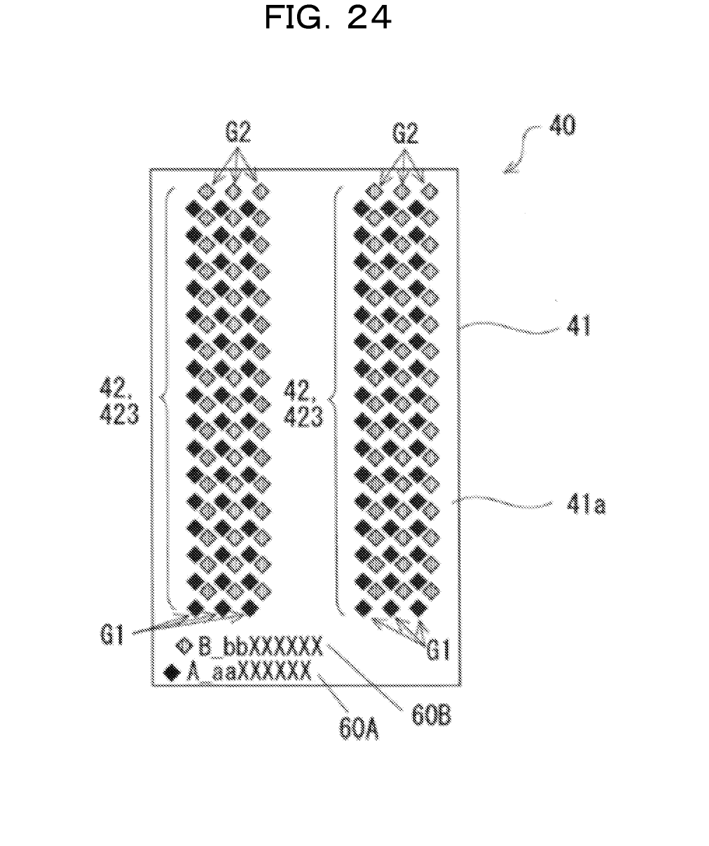

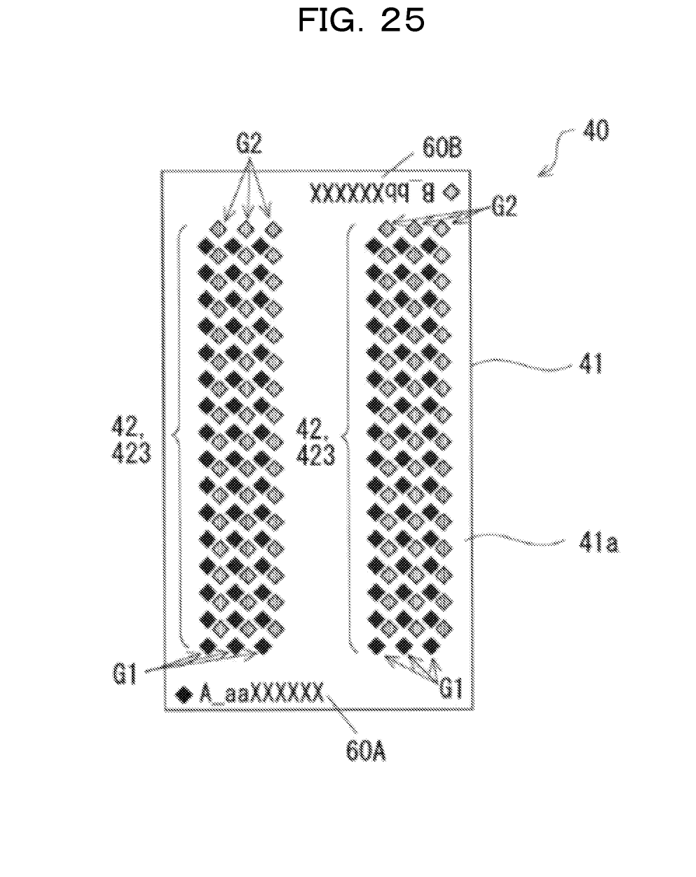

Also, as illustrated in FIGS. 24 and 25, identification markers (identifiers) 60A and 60B, with which the types of the target memory chips of the plurality of connection portion groups are identified, may be formed in the base material 41 of the insertion base 40. As many identification markers such as 60A and 60B are present on the upper surface 41a of the base material 41 as the number corresponding to the connection portion groups G formed corresponding to the types (characteristics) of the memory chips 300. That is, in an example illustrated in FIG. 24, two types of the identification markers, that is, the first identification marker 60A and the second identification marker 60B, which respectively correspond to the first connection portion group G1 (represented by solid rhombuses in FIG. 24) and the second connection portion group G2 (represented by hatched rhombuses in FIG. 24), are provided.

For example, the first identification marker 60A is represented as “A_aaXXXXXX” and the second identification marker 60B is represented as “B_bbXXXXXX”. In the first and second identification markers 60A and 60B, “A” and “B” are alphabetic information for identification of the manufacturer names (vendor names), and “aaXXXXXX” and “bbXXXXXX” are alphabetic information for identification of the model numbers. It is desirable that the identification markers 60A and 60B are present on the upper surface 41a of the base material 41 such that the orientation (vertical direction) of the memory package 30 to be placed on the insertion base 40 correlates with the orientation of the identification marker 60A or 60B in the vertical direction. Thus, the orientation (position) of the memory package 30 to be placed on the insertion base 40 may be recognized in accordance with the orientation of the identification marker 60A or 60B.

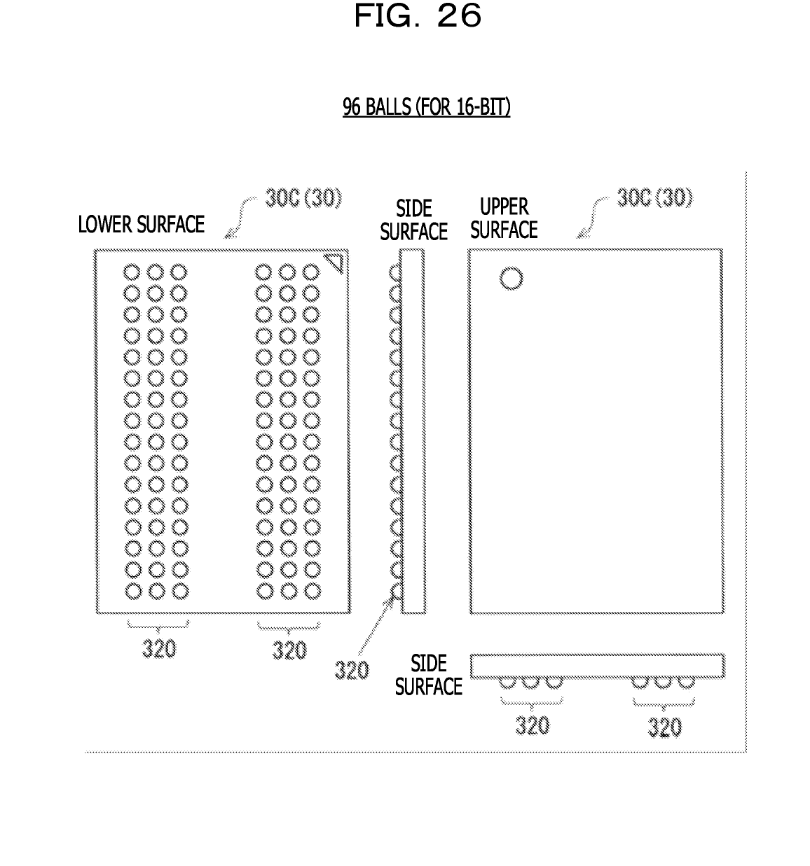

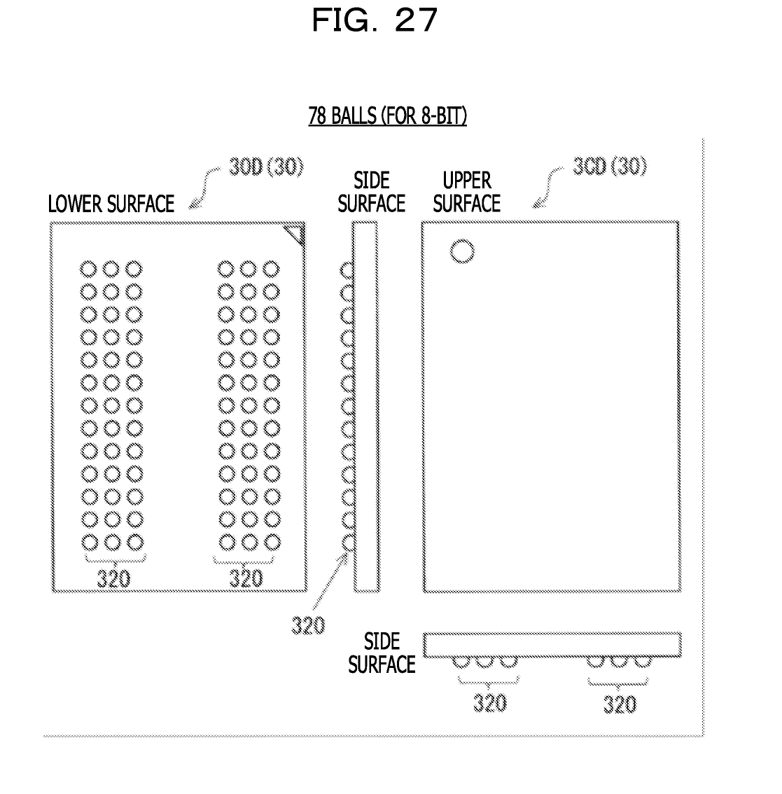

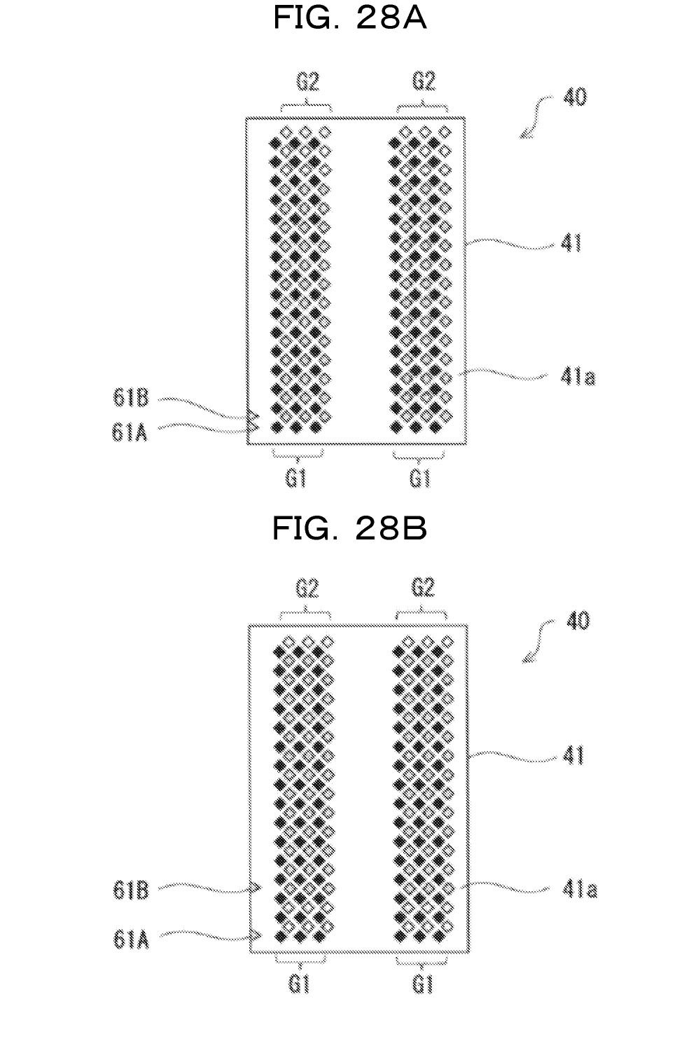

FIG. 26 illustrates a memory package 30C for 16-bit. The memory package 30C includes 96 solder balls 320. FIG. 27 illustrates a memory package 30D for 8-bit. The memory package 30D includes 78 solder balls 320. Here, the pitch of the solder balls 320 of the memory package 30C for 16-bit and the pitch of the solder balls 320 of the memory package 30D for 8-bit are the same. For example, the first connection portion group G1 (represented by solid rhombuses) may be formed so as to be suitable for the characteristics of the memory chip to be placed on the memory package 30C for 16-bit similarly to the insertion base 40 illustrated in FIGS. 28A and 28B. The second connection portion group G2 (represented by the hatched rhombuses and hollow rhombuses) may be formed so as to be suitable for the characteristics of the memory chip to be placed on the memory package 30D for 8-bit. FIGS. 28A and 28B illustrate the insertion base 40 common to the memory package for 16-bit and the memory package for 8-bit.

A first marker 61A and a second marker 61B, which indicate usage regions of the connection portions 42 used for mounting the memory packages 30C and 30D, are disposed on the upper surface 41a of the insertion base 40 illustrated in FIGS. 28A and 28B. In an example illustrated in FIGS. 28A and 28B, triangle marks are present near the long side of the base material 41. The connection portions 42 above the triangle marks are used. It is noted that specific forms and a method of presenting the first marker 61A and the second marker 61B may be appropriately changed. The first marker 61A illustrated in FIGS. 28A and 28B indicates the usage region of the connection portions 42 to be used when the memory package 30C for 16-bit is placed. It is understood that all the connection portions 42 belonging to the first connection portion group G1 (represented by solid rhombuses) are used. The second marker 61B indicates the usage region of the connection portions 42 to be used when the memory package 30D for 8-bit is placed. In the example illustrated in FIGS. 28A and 28B, it is understood that, out of the connection portions 42 belonging to the second connection portion group G2 (represented by hatched rhombuses and hollow rhombuses), the connection portions 42 represented by the hatched rhombuses are used and the connection portions 42 represented by the hollow rhombuses are not used. The position of the second marker 61B may be appropriately changed. Thus, the range of the connection portions 42 not to be used when the memory package 30D is placed may be arbitrarily changed.

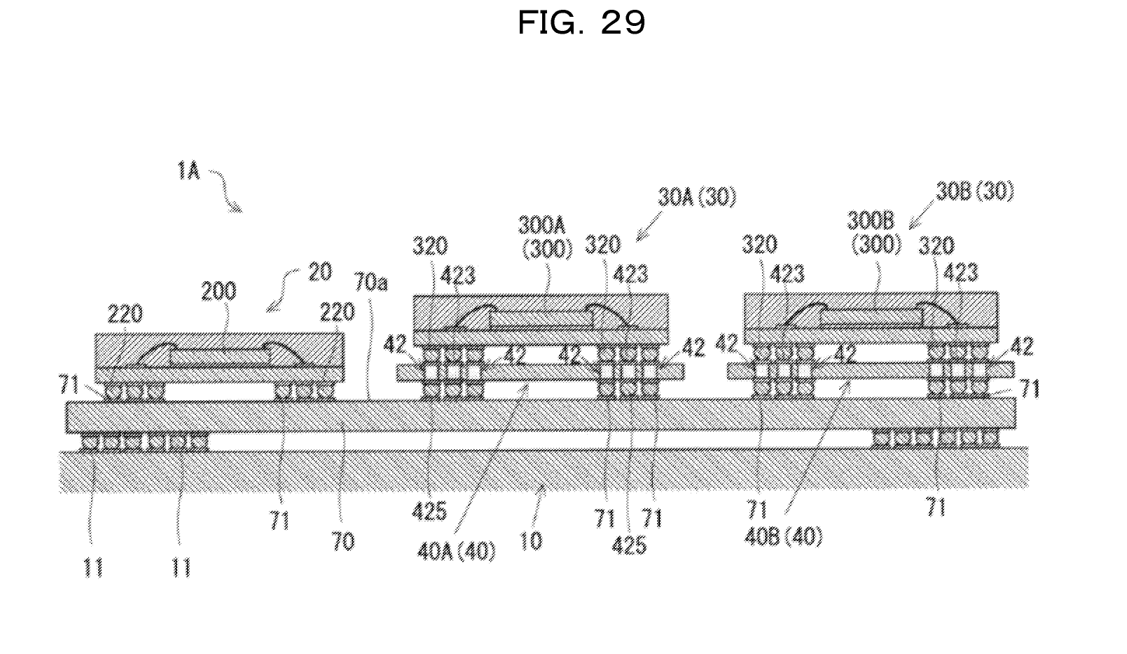

In the wiring board unit 1 according to the above-described embodiment, the memory controller 20 and the plurality of memory packages 30 are directly mounted on the printed wiring board 10 that serves as the mother board. Alternatively, a variant as illustrated in FIG. 29 may be appropriately adopted. In the variant illustrated in FIG. 29, an interposer 70 as a relay board is mounted on the printed wiring board 10 as the mother board, and the memory controller 20 and the plurality of memory packages 30 mentioned above are mounted on the interposer 70. The interposer 70 may be formed of, for example, FR4 (a glass fiber reinforced epoxy resin substrate) or the like. Solder balls are provided on a lower surface of the interposer 70. These solder balls are coupled to the board-side pads 11 of the printed wiring board 10. Despite this, a method of coupling the printed wiring board 10 and the interposer 70 to each other may be appropriately changed.

The difference between a wiring board unit 1A according to the present variant and the wiring board unit 1 according to the above-described embodiment is that, in the wiring board unit 1A, the memory controller 20 and the insertion bases 40 are coupled to board-side pads 71 formed on an upper surface 70a of the interposer 70 instead of being coupled to the board-side pads 11. Other structures of the wiring board unit 1A are the same as those of the embodiment. Next, a method of manufacturing the wiring board unit 1A is described. Initially, the printed wiring board 10, the interposer 70, the memory controller 20, the memory packages 30 (first memory package 30A and second memory package 30B), the insertion bases 40 (first insertion base 40A and second insertion base 40B), and so forth are prepared. Since the method of manufacturing the insertion bases 40 has already been described, detailed description thereof is omitted.

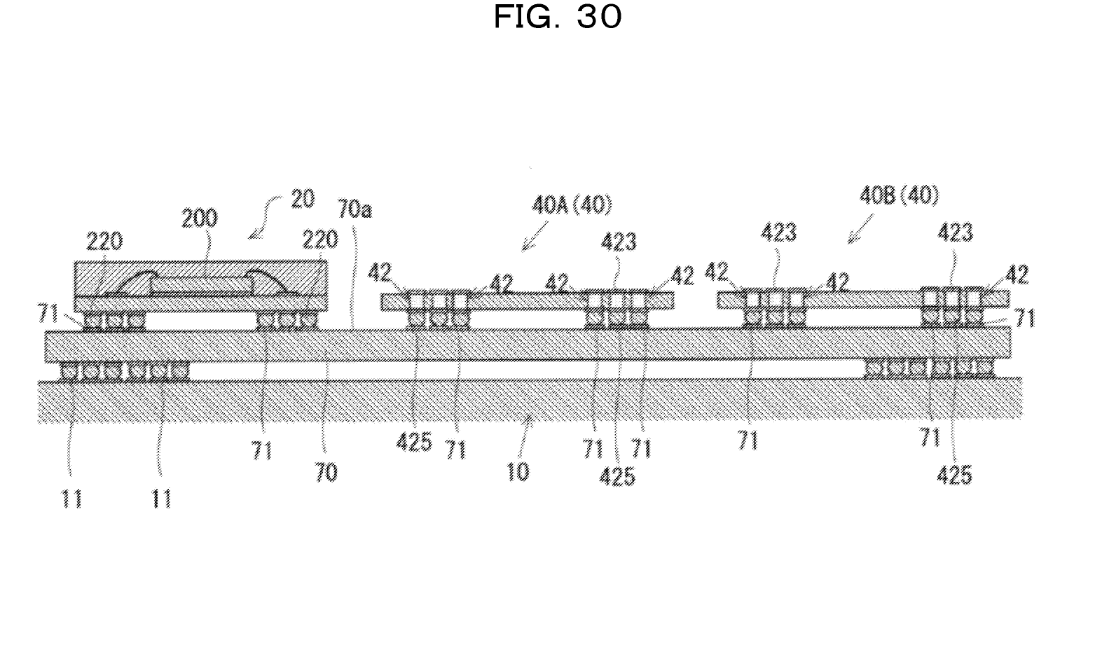

In the manufacture of the wiring board unit 1A, the interposer 70 is initially coupled to the printed wiring board 10. After that, solder paste is supplied onto the board-side pads 71 formed on the upper surface 70a of the interposer 70. After that, the memory controller 20 and the insertion bases 40 are placed on the board-side pads 71. The resultant structure is heated in the reflow oven. Thus, as illustrated in FIG. 30, the memory controller 20 and the insertion bases 40 have been mounted on the interposer 70.

That is, the solder balls 220 of the memory controller 20 and the board-side pads 71 of the interposer 70 are soldered to one another. Thus, the memory controller 20 has been mounted on the interposer 70. Also, the solder balls 425 of the insertion bases 40 and the board-side pads 71 of the interposer 70 are soldered to one another. Thus, the insertion bases 40 (first insertion base 40A and second insertion base 40B) are mounted on the interposer 70. Here, in the first insertion base 40A inserted between the first memory package 30A and the interposer 70, the solder balls 425 of the connection portions 42 belonging to the first connection portion group G1 (see FIG. 8) are soldered to the board-side pads 71. In the second insertion base 40B inserted between the second memory package 30B and the interposer 70, the solder balls 425 of the connection portions 42 belonging to the second connection portion group G2 (see FIG. 8) are soldered to the board-side pads 71.

Next, solder paste is supplied onto the package coupling pads 423 corresponding to the first connection portion group G1 of the first insertion base 40A and the package coupling pads 423 corresponding to the second connection portion group G2 of the second insertion base 40B. After that, the first memory package 30A and the second memory package 30B are placed on the package coupling pads 423 of the first insertion base 40A and the second insertion base 40B, onto which the solder paste has been transferred, and the resultant structure is heated in the reflow oven. As a result, the first memory package 30A and the second memory package 30B have been mounted on the interposer 70, and the wiring board unit 1A illustrated in FIG. 29 is completed. Alternatively, in the manufacture of the wiring board unit 1A, the interposer 70 may be coupled to the printed wiring board 10 after the memory controller 20 and the memory packages 30 have been mounted on the interposer 70. In the present variant, the interposer 70 serves as an example of a wiring board on which the semiconductor packages are mounted.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A method of manufacturing a wiring board unit, the wiring board unit including a semiconductor package that includes a memory chip, a wiring board on which the semiconductor package is mounted, and an insertion base inserted between the wiring board and the semiconductor package, the method comprising:
forming a plurality of connection portion groups in a base material, the connection portion groups each including a plurality of connection portions that each electrically connect a board-side pad of the wiring board and an external terminal of the semiconductor package to each other, the connection portion groups being selectively used in accordance with a type of the memory chip;
forming the insertion base such that resistances of the connection portions included in the connection portion groups are adjusted in accordance with types of target memory chips; and
connecting the external terminals and the board-side pads to one another by using the connection portion group selected in accordance with the type of the memory chip from the plurality of connection portion groups of the insertion base having been formed.

2. The method according to claim 1,
wherein, in a flat surface of the base material, the connection portions included in each of the plurality of connection portion groups are arranged at positions shifted in an arrangement direction from positions where the connection portions included in the other connection portion group or connection portion groups are arranged, and the plurality of connection portions are generally arranged in a staggered pattern.

3. A method of manufacturing an insertion base, the insertion base being inserted between a semiconductor package and a wiring board, the semiconductor package including a memory chip, the semiconductor package being mounted on the wiring board, the method comprising:
forming a plurality of connection portion groups in a base material, the connection portion groups each including a plurality of connection portions that each electrically connect a board-side pad of the wiring board and an external terminal of the semiconductor package to each other, the connection portion groups being selectively used in accordance with a type of the memory chip; and
adjusting resistances of the connection portions included in the connection portion groups in accordance with types of target memory chips.

4. A wiring board unit comprising:
a semiconductor package that includes a memory chip;
a wiring board on which the semiconductor package is mounted; and
an insertion base inserted between the wiring board and the semiconductor package,
wherein the insertion base includes
a base material, and
a plurality of connection portion groups provided in the base material, the connection portion groups each including a plurality of connection portions that each electrically connect a board-side pad of the wiring board and an external terminal of the semiconductor package to each other, the connection portion groups being selectively used in accordance with a type of the memory chip; and
wherein resistances of the connection portions included in the connection portion groups are adjusted in accordance with types of target memory chips.

5. An insertion base inserted between a semiconductor package and a wiring board, the semiconductor package including a memory chip, the semiconductor package being mounted on the wiring board, the insertion base comprising:
a base material; and
a plurality of connection portion groups provided in the base material, the connection portion groups each including a plurality of connection portions that each electrically connect a board-side pad of the wiring board and an external terminal of the semiconductor package to each other, the connection portion groups being selectively used in accordance with a type of the memory chip,
wherein resistances of the connection portions included in the connection portion groups are adjusted in accordance with types of target memory chips.
